(19) United States
(12) Patent Application Publication
(10) Pub. No.: US 2022/0344967 A1
(43) Pub. Date: Oct. 27, 2022

(54) RACK BASED UPS SYSTEM

(71) Applicant: Panduit Corp., Tinley Park, IL (US)

(72) Inventor: Ronald A. Nordin, Naperville, IL (US)

(73) Assignee: Panduit Corp., Tinley Park, IL (US)

(21) Appl. No.: 17/241,486

(22) Filed: Apr. 27, 2021

(51) Int. Cl. H02J 9/06; H05K 7/14

(52) U.S. Cl. CPC H02J 9/062; H05K 7/1492

(57) ABSTRACT

A system for providing power to a server cabinet has at least one power distribution unit PDU located vertically positioned near a sidewall of a server cabinet such as to not take up any U-space and at least one battery connected to the PDU and positioned near a sidewall such as to not take up any U-space of the server cabinet.

### FIELD OF THE INVENTION

The present invention related generally to providing power to server cabinets and more specifically to providing power with a battery backup that does not take up any U-space in the server cabinet.

### BACKGROUND

Data Centers rely on UPS systems to increase their reliability and availability. Traditionally these UPS systems have been implemented as a centralized system, providing power to all the IT-Equipment within the facility during power outages. A new trend has begun where instead of a centralized system the UPS units are distributed through out the Cabinets in the Data Center. This rack-based UPS equipment supply power to the cabinet's IT-Equipment that they are housed in (and they can also serve neighboring cabinets if required). The rack-based UPS units can be implemented in a number of ways, from a tradition manner to a novel technique (the subject of this application) where the UPS is integrated with the rack-PDU.

FIG. 1A shows the Uptime Institute's Tier levels and definitions for data centers. These tier levels help define the topology of the equipment of a data center in order to achieve a certain level of reliability. When focused at a subset of the equipment within a data center, for example just a particular cabinet and the equipment inside, one can use these tier level definitions as guidelines to discern between different cabinet implementations. As shown in FIG. 1B, depending how the rack-based UPS, rack-PDU, and the utility power is applied, one can implement topologies that can achieve Tier 1 through Tier 4.

FIGS. 2 through 4, show various cabinet implementations containing rack-PDUs, UPS, and IT-Equipment (e.g., Servers). FIG. 2 shows a more convention implementation where standard rack-PDUs and standard rack-based UPS equipment is utilized. FIG. 3 expands configuration #5 as shown in FIG. 2. The power connectivity between the cabinet's IT-Equipment, a conventional Rack-PDU, and a Rack-Based UPS are shown. In this configuration, if the main utility power (PWR-BUS-A) goes down, the UPS will provide AC power to the Servers for a pre-determined amount of time (dependent upon the battery capacity used in the UPS) to allow the DC's Generator system to come on-line (if so employed). The batteries are charged via an AC input from the PDU. The UPS in this configuration must be in the standby mode and activates only if the AC main power goes down. The Servers power supplies are in the active-standby mode. The tier level of this configuration is probably 1.5 because there are two power supplies (redundant) within the IT-Equipment adding to the Servers reliability.

FIG. 4 expands configuration #4 as shown in FIG. 2. The power connectivity between the cabinet's IT-Equipment, a conventional Rack-PDU, and Rack-Based UPS are shown. If the main utility power (PWR-BUS-A) goes down, the UPS will provide AC power to the Servers for a pre-determined amount of time (dependent upon the battery capacity used in the UPS) to allow the DC's Generator system to come on-line (if so employed). The batteries are charged via an AC input from the PDU. The UPS in this configuration can be in the active standby (pass-through) or double conversion mode and activates only if the AC main power goes down. The Server utilizes a single power supply. The tier level of this configuration is probably 1+ because of the presence of the UPS. Note that the UPS has an unconventional design to it, due to the matching inlet and outlet ports where a pass-through mode is utilized.

FIG. 5 expands configuration #2 as shown in FIG. 2. The power connectivity between the cabinet's IT-Equipment, a conventional Rack-PDU, and Rack-Based UPS is shown. If one of the main utility power connections (e.g., PWR-BUS-A or PWR-BUS-B) goes down, the redundant main utility power connection will support the IT-Equipment. If both fail, the UPS's will provide AC power to the Servers for a pre-determined amount of time (dependent upon the battery capacity used in the UPS). The batteries within the UPSs are charged via an AC input from each of the PDUs. The UPS in this configuration can be in the active standby (pass-through) or double conversion mode and activates only if the AC main power goes down. The tier level of this configuration is 4, the highest level. Note that both UPSs are needed in this configuration to obtain a tier level of 4 (e.g., configuration 3 shown in FIG. 2 will only be able to achieve a tier level of 3). Also note that these UPS's have an unconventional design to it due to the matching inlet and outlet ports where a pass-through mode is utilized.

### SUMMARY

A system for providing power to a server cabinet has at least one power distribution unit PDU located vertically positioned near a sidewall of a server cabinet such as to not take up any U-space and at least one battery connected to the PDU and positioned near a sidewall such as to not take up any U-space of the server cabinet.

### BRIEF DESCRIPTION OF THE FIGURES

FIGS. 1A and 1B show the Uptime Institute's Tier levels and definitions for data centers.

FIG. 2 shows a more convention implementation where standard rack-PDUs and standard rack-based UPS equipment is utilized.

FIG. 3 expands configuration #5 as shown in FIG. 2.

FIG. 4 expands configuration #4 as shown in FIG. 2.

FIG. 5 expands configuration #2 as shown in FIG. 2.

FIG. 6 shows a novel configuration of a Server cabinet utilizing a novel rack-based PDU with integrated UPS (rack-PDU-UPS) functionality to power the cabinets equipment.

FIG. 7 shows an implementation of an integrated rack-PDU-UPS.

FIG. 8 shows various implementations of a Battery module.

FIG. 9 shows another implementation of a Server cabinet with rack-based PDU and a rack-based UPS to power the cabinets IT-equipment.

FIG. 10 shows a comparison between implementations arranged in a localized Tier ˜1.5 level.

FIG. 11 shows a comparison between implementations arranged in a localized Tier 4 level.

FIG. 12 shows an example construction of a cabinet that supports an integrated rack-PDU-UPS.

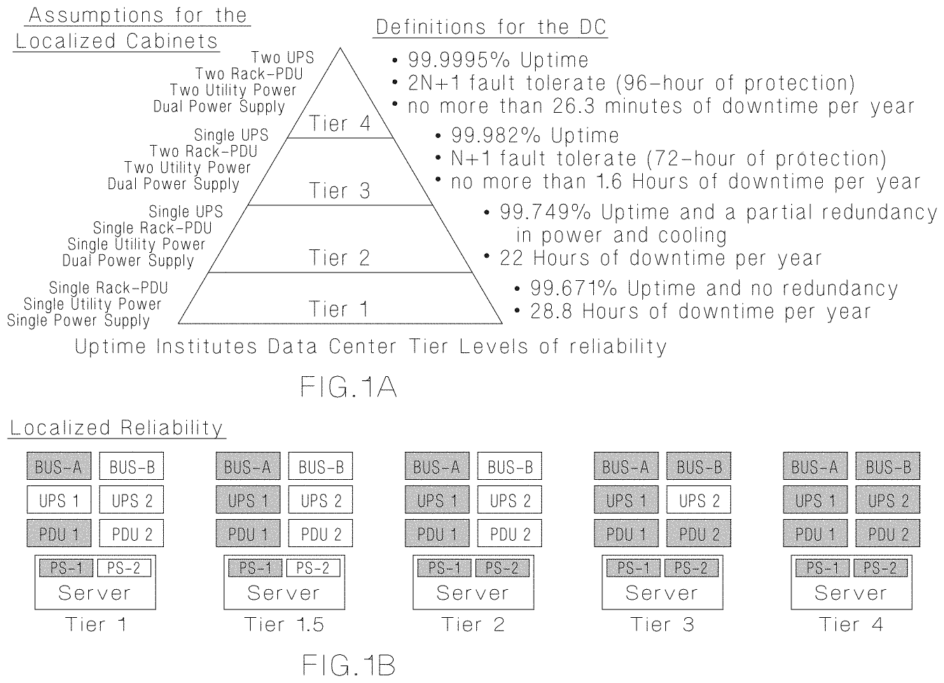

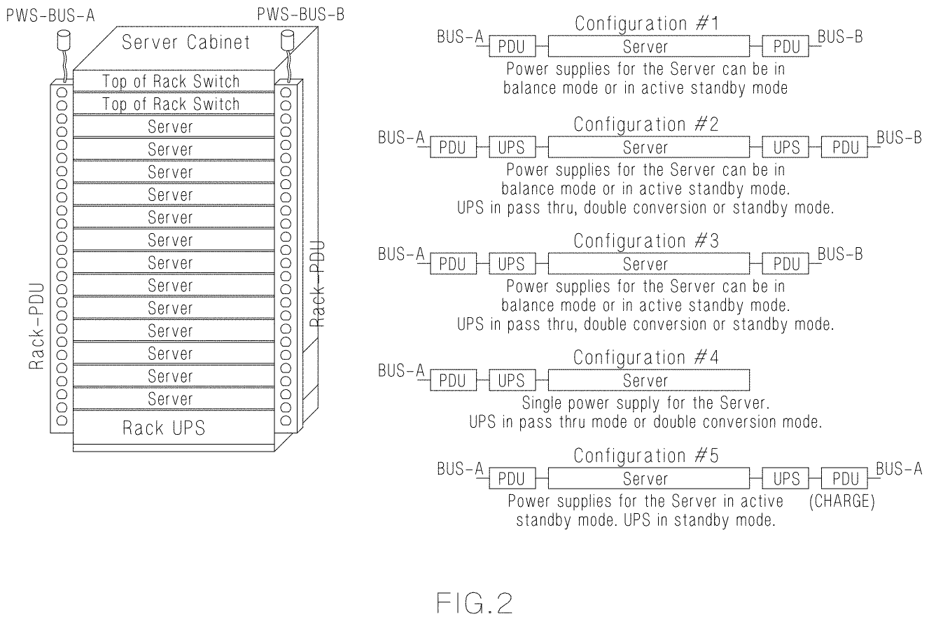

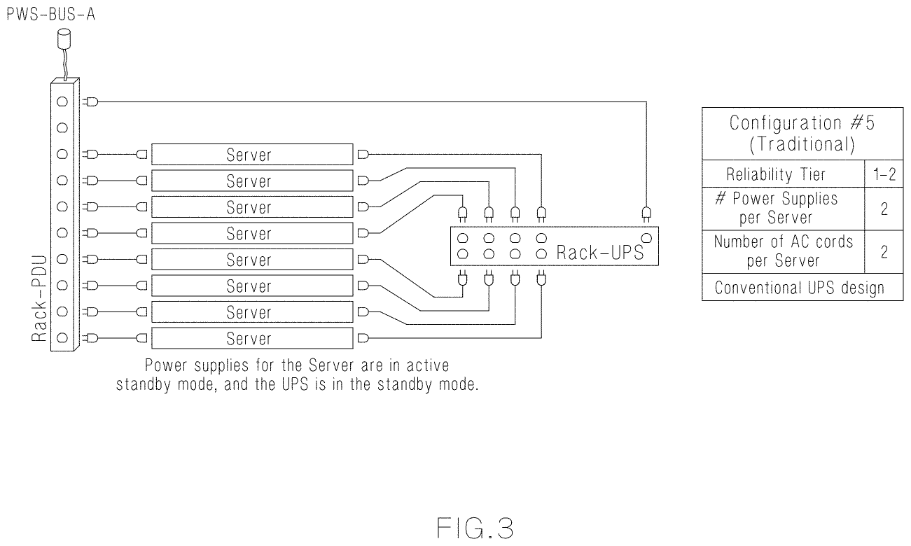

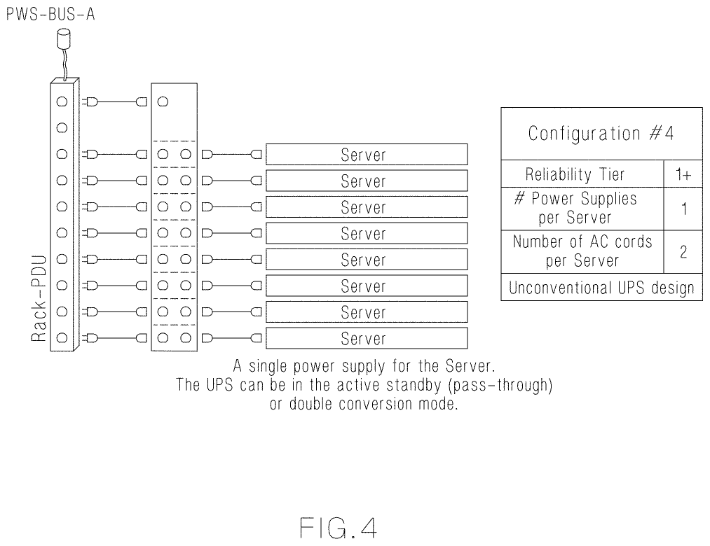

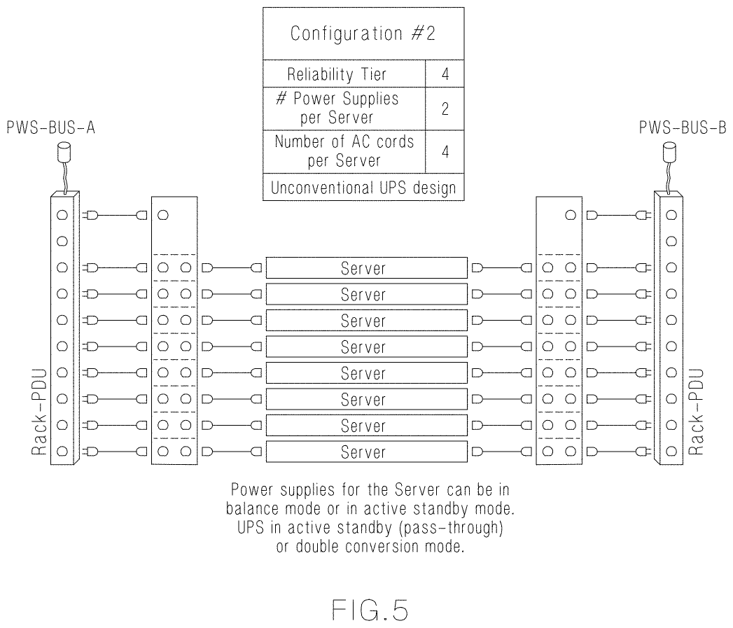

### DETAILED DESCRIPTION OF THE INVENTION

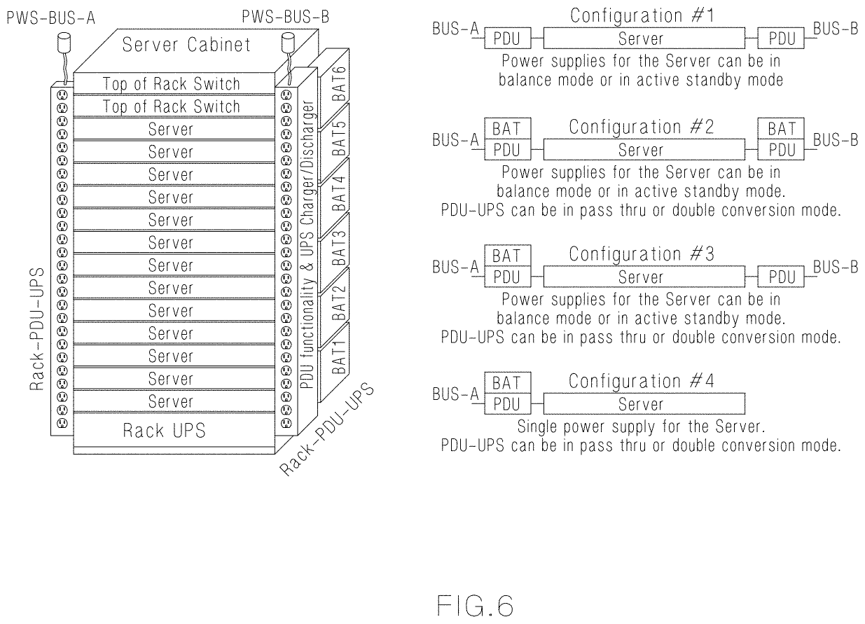

FIG. 6 shows a novel configuration of a Server cabinet utilizing a novel rack-based PDU with integrated UPS (rack-PDU-UPS) functionality to power the cabinets equipment. As shown on the right side of the Figure, the rack-PDU-UPS can be configured in a number of ways based on the Tier level desired. Several advantages that this combination of functionality provides are:
1. The functionality of a rack-based UPS that does not take up rack space (e.g., zero RU);
2. Fewer AC patch cords to physically manage (easier installation practices); and
3. Improved UPS manageability (scalability options, ease of scaling tier levels, battery resource sharing which can be priority based across the PDU span of Servers).

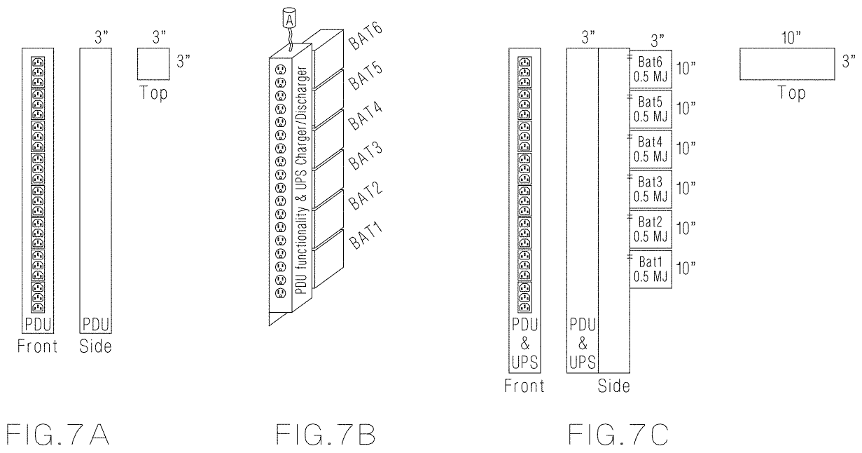

FIG. 7 shows an implementation of an integrated rack-PDU-UPS. As shown in the Figure, a comparison of size is shown between a traditional Rack-PDU (A) versus a Rack-PDU-UPS (B and C). The integrated rack-PDU-UPS has the same height and depth dimensions but has ˜3× width as compared to a traditional rack-PDU. The Battery modules can be scaled from 1 to 6 in this particular implementation. Each of the battery modules have an energy of greater than 500 kJ. With 6 battery modules, the capacity of the rack-PDU-UPS is 3 MJ. If the rack-PDU-UPS is supplying 10 kW, then the UPS can supply power for approximately 300 sec (=5 minutes). This seems to be an adequate capacity for most cabinets within a DC.

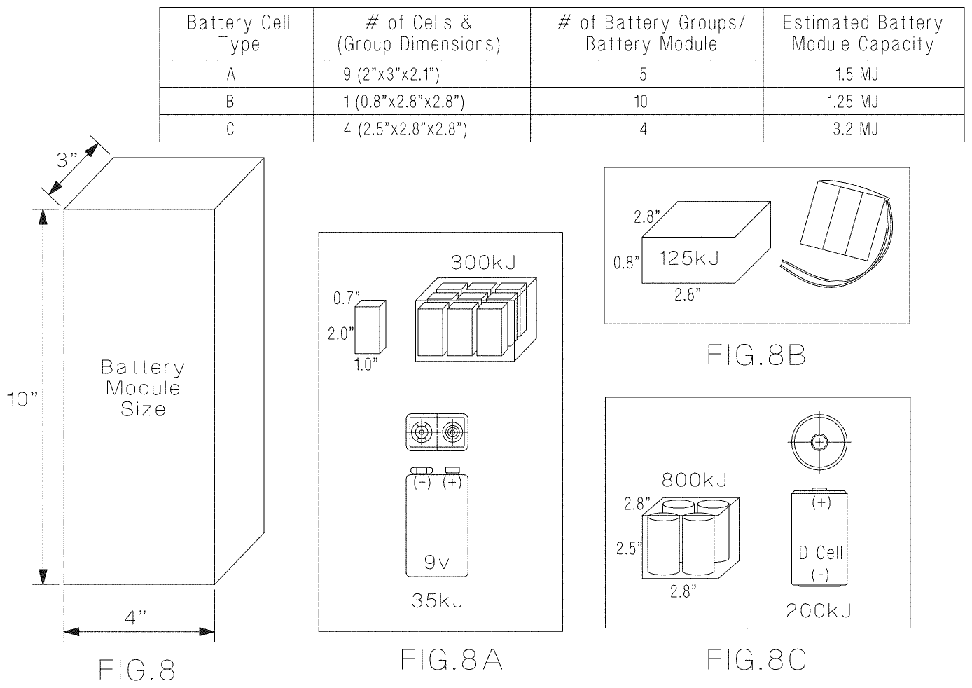

FIG. 8 shows various implementations of a Battery module. The three implementation examples shown in the Figure have an energy capacity of more than 1000 kJ.

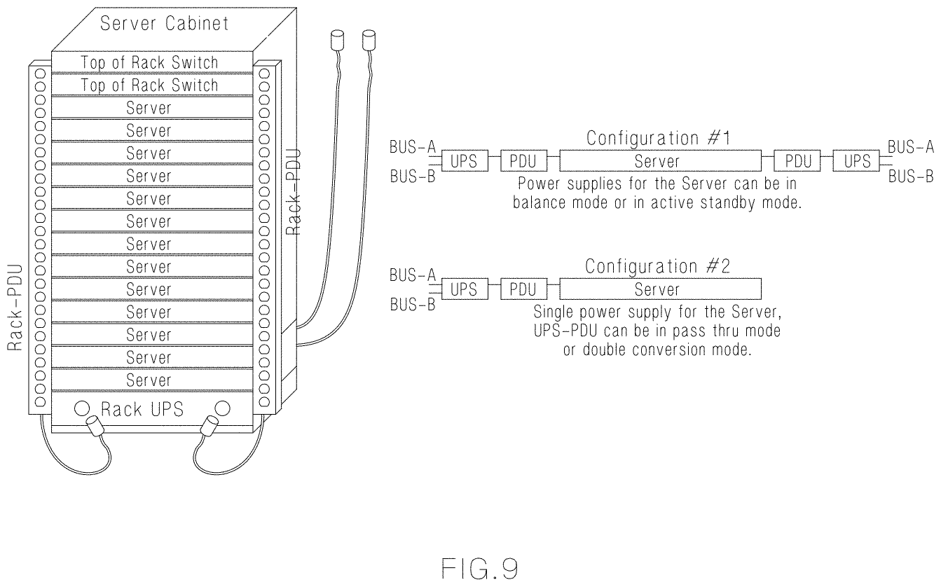

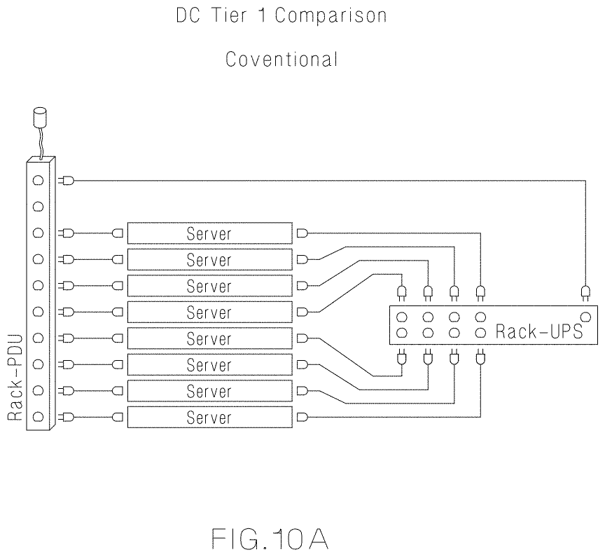

FIG. 9 shows another implementation of a Server cabinet with rack-based PDU and a rack-based UPS to power the cabinets IT-equipment. The UPS here takes input from the 3-phase bus and outputs into the rack-PDUs. As shown on the right side of the Figure, rack-based PDU and the rack-based UPS can be configured in a number of ways based on the Tier level desired. Several advantages that this type of UPS offers include:
1. 3-phase input and single-phase output towards the rack-PDU means that the installer does not have to load balance the Servers,
2. The UPS can auto phase balance into the UPS creating an always balanced system, and
3. Easy installation (just like a traditional rack-PDU)
   Some of the disadvantages include:
1. Takes up valuable RU space in the rack; and
2. Necessitates another 3-phase power cord towards the power bus system.

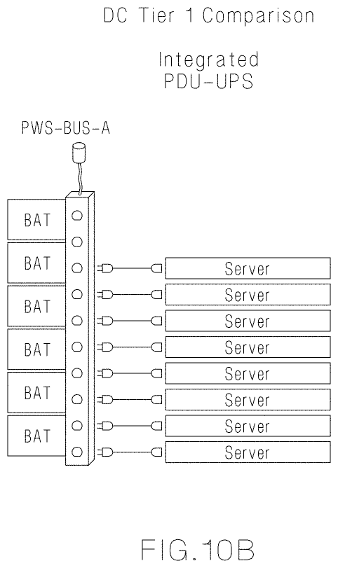

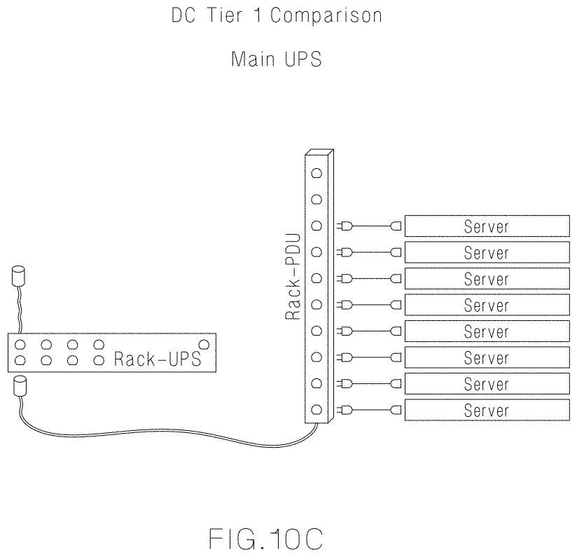

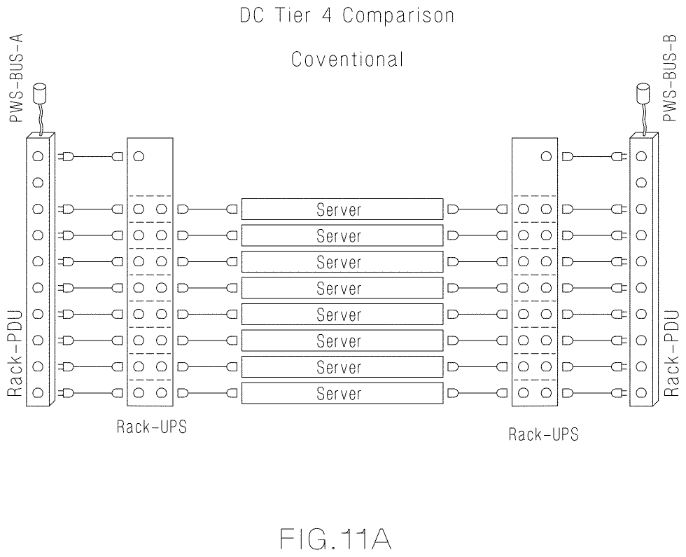

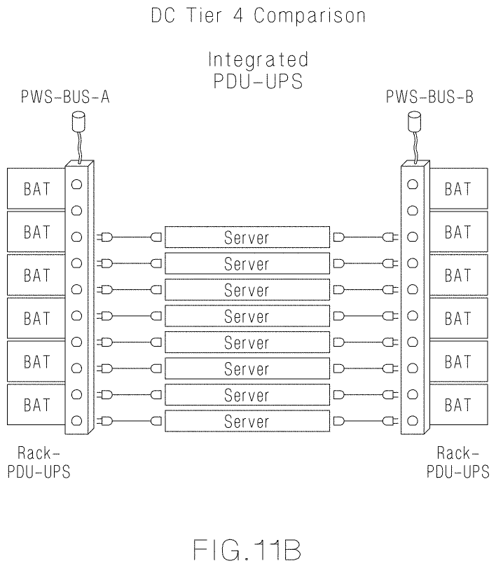

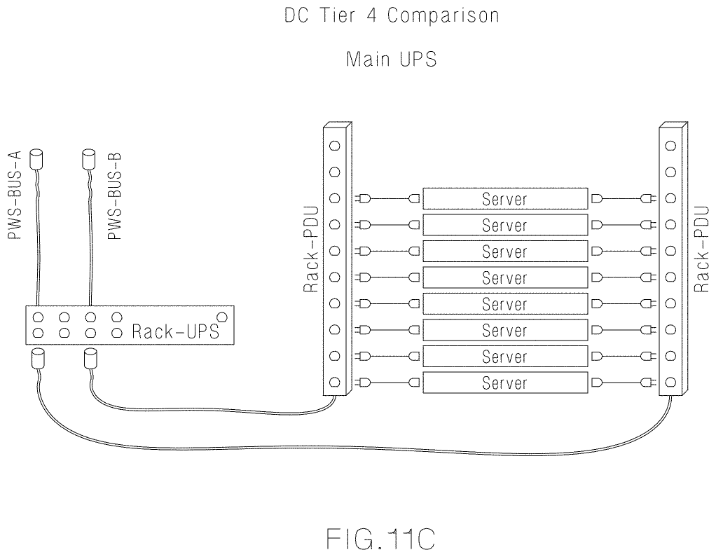

FIG. 10 shows a comparison between implementations arranged in a localized Tier ˜1.5 level. The conventional arrangement shown in (A), which has two power supplies per Server, two AC cords per Server, and takes up valuable RU space whereas the implementations shown in (B) and (C) have a single power supply and a single AC cord per server. The implementations in (B) and (C) are more efficient and much simpler and represents a more “standard” way of installing power to the Servers. Implementation (C) does take up valuable RU space as did (A).

FIG. 11 shows a comparison between implementations arranged in a localized Tier 4 level. The conventional arrangement shown in (A), has two power supplies per Server and four AC cords per Server, whereas the implementations shown in (B) and (C) have two power supply and two AC cord per server. The implementations in (B) and (C) are much more simple and “standard” way of installing power to the Servers. Only (B) does not take up valuable RU space within the cabinet.

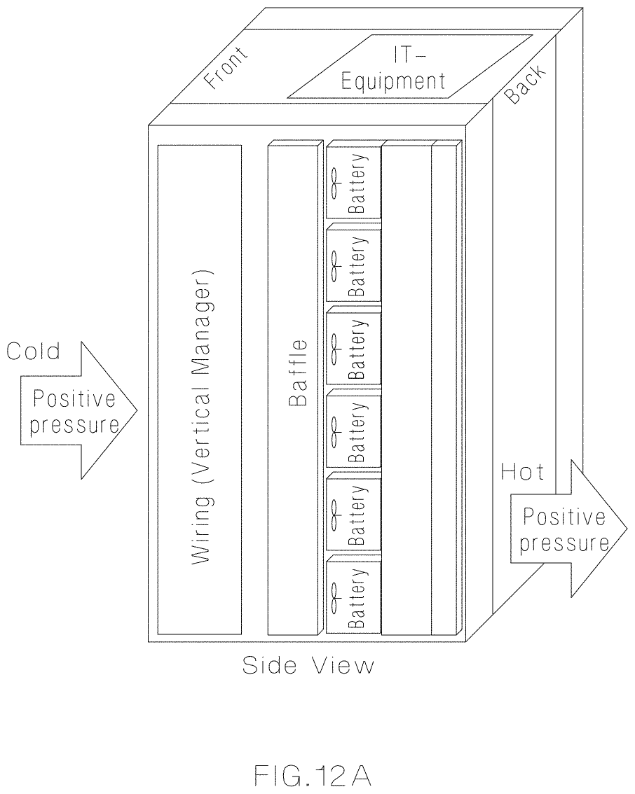

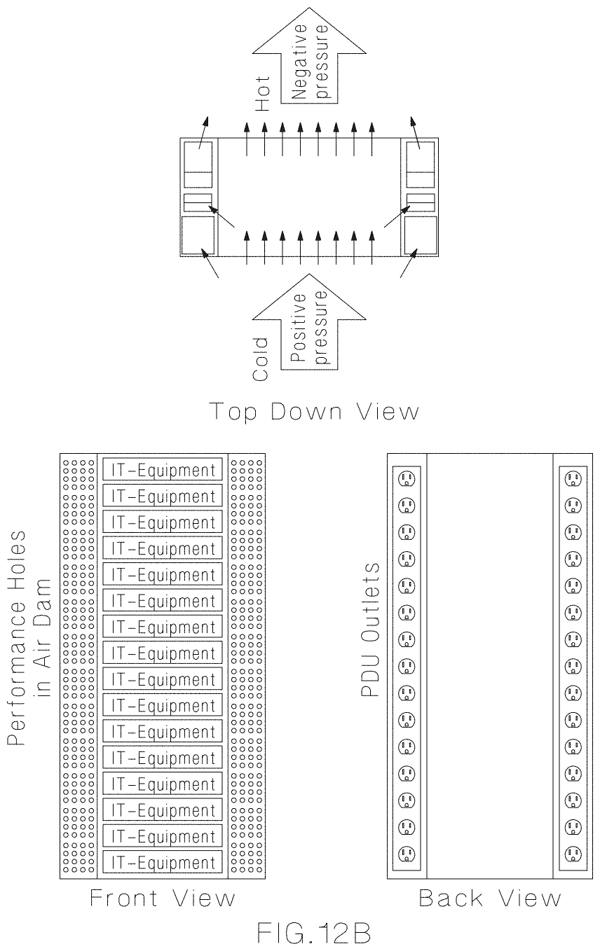

FIG. 12 shows an example construction of a cabinet that supports an integrated rack-PDU-UPS. Note that the UPS needs cool air just like the input of the IT-Equipment consume. Typically, behind the vertical wire manager an air dam exists to keep the cool air coming in from the front of the cabinet to be channeled towards the IT-Equipment's front face. The air dam should be perforated to allow a pre-determined amount of cool air to go towards the rack-PDU-UPS. A baffle may be added so as the air from the air dam is routed efficiently to the optionally installed battery modules. The air transitions from the battery modules to the UPS-PDU portion of the unit.

1. A system for providing power to a server cabinet comprising:
at least one power distribution unit PDU located vertically positioned near a sidewall of a server cabinet such as to not take up any U-space; and
at least one battery connected to the PDU and positioned near a sidewall such as to not take up any U-space of the server cabinet.

2. The system of claim 1 wherein the battery is integrated into the PDU.

3. The system of claim 1 wherein the at least one PDU comprises a first PDU and a second PDU and further wherein the PDUs are configured in a balance mode.

4. The system of claim 1 wherein the at least one PDU comprises a first PDU and a second PDU and further wherein the PDUs are configured in live standby mode.
